(19) United States
(12) Patent Application Publication
(10) Pub. No.: US 2002/0003252 A1
(43) Pub. Date: Jan. 10, 2002

(54) FLASH MEMORY CIRCUIT WITH WITH RESISTANCE TO DISTURB EFFECT

(76) Inventor: RAVI IYER, BOISE, ID (US)

Correspondence Address: SCHWEGMAN LUNDBERG WOESSNER & KLUTH, PO BOX 2938, MINNEAPOLIS, MN, 55402

(21) Appl. No.: 09/145,873

(22) Filed: Sep. 3, 1998

(51) Int. Cl. H01L 29/76; H01L 21/82

(52) U.S. Cl. 257/315; 257/390; 438/128; 438/201

(57) ABSTRACT

Flash memories, a type of computer memory for storing digital data, include millions of individual memory cells arranged and interconnected in rows and columns. Each memory cell includes a floating-gate transistor. Although quite popular because of their low cost and high storage capacity, these memories suffer from a problem known as the disturb effect, during which desired write or erase operations on targeted memory cells inadvertently lead to writing or erasing nearby nontargetted memory cells. Current approaches to solving this problem are undesirable because they require extra circuitry. Accordingly, one embodiment of the invention is a floating-gate transistor which has floating gate with a work function (an electrical property) that is greater than that of conventional floating-gate transistors, or 4.15 electron-volts. The greater work function not only inhibits the disturb effect but also increases the life of memory cells and allows use of lower write voltages.

### FIELD OF INVENTION

The present invention concerns memory circuits, particularly nonvolatile memory circuits and more particularly, flash memory circuits.

### BACKGROUND OF THE INVENTION

Memory circuits are vital components in computers and other electronic systems which require storing data for future use. Memory circuits that lose their data after loss of power are called volatile memories, whereas those that keep their data are called nonvolatile memories. One kind of nonvolatile memory circuit is called a flash memory circuit, dubbed “flash” because of its near instantaneous total erase feature. Flash memory circuits are sometimes called “electrically erasable and programmable read-only memories, or EEPROMs for short.

A typical flash memory circuit is an interconnected network of millions of microscopic memory cells. Each memory cell typically stores an electric charge representing a one or zero data bit. The memory cells are usually arranged as a rectangular array having a specific number of rows and columns, with each cell having a unique address based on its row and column position. Cells that belong to the same column share a connection to a wire known as a bit line, and cells that belong to the same row are connected to a wire known as a word line. Accessing a particular memory cell entails applying appropriate voltages to the bit and word line corresponding to the column and row of that cell.

Each memory cell includes a floating-gate transistor (FGT). In addition to its namesake floating gate, a floating-gate transistor has three other major features: a control gate, a source region, and a drain region. The floating gate - - - typically a flat conductive plate embedded in a layer of insulation - - - serves as a charge-storage element which can be charged or discharged to represent a “0” or “1.” The control gate, also a flat conductive plate, lies centered above the floating gate, and the source and drain regions lie underneath and to the left and right of the floating gate in a layer of silicon. The source and drain regions define the ends of a silicon region called a channel. The control gate and source region of each cell are connected respectively to its corresponding bit and word lines, and the drain regions of all cells are connected together.

Normal operations of the flash memory circuit include writing, reading, and erasing its memory cells. Writing, sometimes called recording or programming, usually entails applying a write voltage, for example, 6 volts across the bit and word lines of a memory cell, thereby charging its floating gate. Reading the memory cell entails applying a read voltage, typically 4 volts, across its bit and word lines. This voltage combination causes an electric current to flow from the source, through the channel, to the drain. Circuitry coupled to the memory cell senses the amount of current and outputs a data signal representing a one or zero data bit. To erase a memory cell, one applies an erase voltage, typically 12 volts, to its source region, thereby discharging the floating gate. It is common to erase all or a block of memory cells simultaneously.

One problem in conventional flash memory circuits is the disturb effect. The effect occurs when a write or erase operation on one memory cell or more typically a block of memory cells affects the charges of nearby memory cells. Although a single occurrence of the disturb effect causes only a minor decrease or increase in the charge of nearby memory cells, repeated occurrences add up, ultimately changing stored 1s to 0s and 0s to 1s and thus corrupting the stored data.

There have been a number of attempts to counter the disturb effect, but each has its shortcomings. For example, one researcher proposed a memory cell with a divided control gate structure, with one side for use in programming the cell and the other side for use in erasing the cell. (See Seiichi Aritome et al, Reliability Issues of Flash Memory Cells, in Proceedings of the IEEE, Vol. 81, May 1993.) However, extra control lines are required to operate both sides of the divided control gate. Another approach entails adding special circuitry to count the number of times a block of memory cells may be subject to the disturb effect and then automatically refreshing, or rewriting, data to the affected cells when the count reaches a certain number. (See U.S. Pat. No. 5,715,193 which is entitled “Flash Memory System and Method for Monitoring the Disturb Effect” and incorporated herein by reference.) Although both approaches ameliorate data corruption resulting from the disturb effect, they do so at the cost of adding space-consuming circuitry to already crowded memory circuits.

Accordingly, there remains a need for a nonvolatile memory circuit that effectively inhibits or resists the disturb effect without the addition of extra circuitry.

### SUMMARY OF THE INVENTION

To address these and other needs, the inventor has developed a disturb-resistant nonvolatile memory circuit. In one embodiment, each memory cell of a nonvolatile memory circuit includes a floating-gate transistor having a floating gate with a work function greater than about 4.15, the work function of conventional silicon floating gates. Examples of materials which have this greater work function include titanium-nitride-tungsten alloy, tungsten, or titanium silicide, nickel, copper, gold, or silver. The greater work function makes it more difficult to inadvertently remove charge from the floating gates of nontargetted memory cells during erase operations. Moreover, the greater work function also reduces the write voltage required to charge the memory cell, increases the life of the memory cell, improves erase cycle endurance, and reduces threshold voltage variation after erasure.

### BRIEF DESCRIPTION OF THE DRAWINGS

FIG. 1 is a cross-sectional view of a nonvolatile memory cell embodying, or incorporating, the disturb-resistant features of the present invention; and

FIG. 2 is a block diagram of a flash memory circuit which itself incorporates one or more disturb-resistant memory cells of the present invention.

### DESCRIPTION OF THE PREFERRED EMBODIMENTS

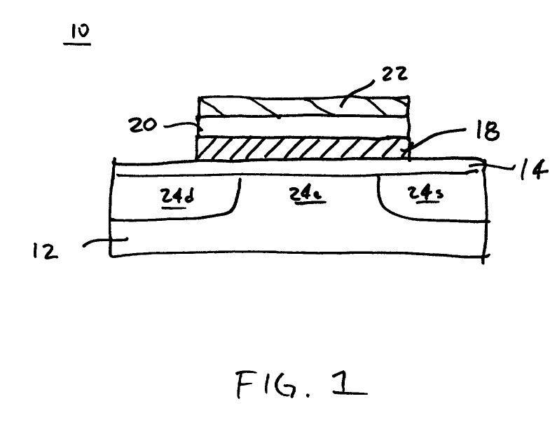

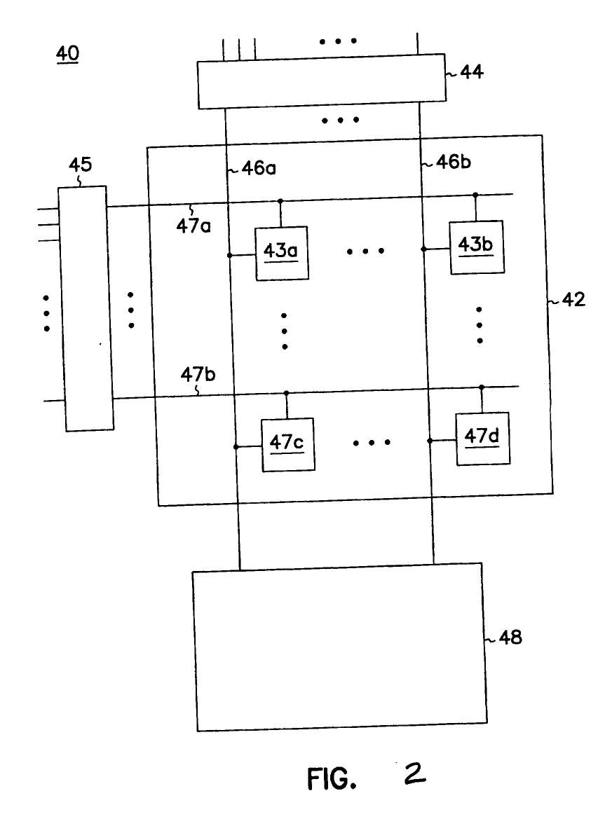

The following detailed description, which references and incorporates FIGS. 1 and 2, describes and illustrates specific embodiments of the invention, specifically a disturb-resistant memory cell and a memory circuit incorporating one or more of these cells. These embodiments, offered not to limit but only to exemplify and teach the invention, are shown and described in sufficient detail to enable those skilled in the art to implement or practice the invention. Thus, where appropriate to avoid obscuring the invention, the description may omit certain information known to those of skill in the art.

### Exemplary Disturb-resistant Nonvolatile Memory Cell

FIG. 1 shows an exemplary structure of a nonvolatile memory cell 10, sometimes called a floating-gate transistor or a floating-gate-tunneling oxide (FLOTOX) transistor. Cell 10, formed using conventional NMOS or CMOS processing techniques for example, includes a substrate 12. The term “substrate,” as used herein, encompasses a semiconductor wafer as well as structures having one or more insulative, semi-insulative, conductive, or semiconductive layers and materials. Thus, for example, the term embraces silicon-on-insulator, silicon-on-sapphire, and other advanced structures.

In addition to substrate 12, memory cell 10 includes a first gate insulation layer 14, which consists of an insulative material, such as silicon dioxide. In the exemplary embodiment, gate insulation layer 14 is about 100 Angstroms thick. However, in other embodiments, layer 14 has a lesser or greater thickness, such as 50 or 150 Angstroms.

Memory cell 10 also includes a floating gate 18 on first gate insulation layer 14, a second gate insulation layer 20 on floating gate 18, and a control gate 22 on insulation layer 20. The exemplary embodiment forms floating gate 18 from a material or material composition having a work function greater than about 4.15 electron-volts (eV), forms gate insulation layer 20 from silicon dioxide, and forms control gate 22 from conventionally doped polysilicon. The work function of conventional heavily n-doped polysilicon floating gates is about 4.15 electron-volts (eV.) Examples of materials which have a greater work function greater than 4.15 electron-volts include tungsten (4.55), nickel (4.55), copper (4.7), gold (5.0), silver (5.1), titanium silicide (4.5-4.9), titanium-nitride-tungsten alloy (4.3-4.9), platinum (5.6), iridium (5.2), and selenium (6.0). (As used herein, work function refers to the difference between the vacuum, or free-electron, energy of a material and its Fermi energy.)

Nonvolatile memory cell 10 further includes self-aligned drain and source regions 24d and 24s in substrate 12. (Conventionally p-doped silicon substrates have work functions ranging from 4.9 to 5.1, depending on dopant concentrations.) Although the invention encompasses any drain-source diffusion profile, the exemplary embodiment presents the source region with a deeper diffusion than the drain region to enhance erase operations. An exemplary implantation dose for the source and drain regions is 10¹⁵ per square centimeter. Drain and source regions 24d and 24s define the length of semiconductive channel region 24c. (For sake of clarity, FIG. 1 omits the drain and source contacts that are generally part of any commercial memory cell.)

Nonvolatile memory cell 10, with the exception of its disturb-resistant attributes, operates as a conventional flash memory cell in writing, reading, and erasing operations. Writing, otherwise known as recording or programming, entails applying a write voltage differential of approximately +6 volts across control gate 22 and drain region 24d, while source region 24s is at approximately zero volts. Under these bias conditions, electrons from channel region 24c travel, more precisely tunnel, through gate insulation layer 14 to floating gate 18, where they accumulate to form an electric charge representative of a one or zero data state. In the exemplary embodiment, charge transfer to floating gate 18 occurs through hot-electron injection.

Read operations entail applying a read voltage differential, approximately four volts across control gate 22s and source region 24s. The read voltage differential causes an electric current to flow from source 24s, through channel 24c, to drain 24d, with the current magnitude dependent on whether floating gate 18 presently stores an electric charge. The presence of an electric charge on floating gate 18 shifts the effective threshold voltage of floating-gate transistor 10, making it, more precisely channel 24c, less conductive for any gate-to-source bias voltage. In the exemplary embodiment, the presence of sufficient negative charge on floating gate 18 prevents channel 24c from conducting an appreciable current with application of the differential read voltage.

Erasing memory cell 10 entails grounding control gate 22, applying an erase voltage of approximately +12 volts to source region 24s, and “floating” drain region 24d. Under this bias condition, any charge on floating gate 18 travels or tunnels through gate insulation 14 into channel region 24c, according to Fowler-Nordheim tunneling in the exemplary embodiment. Thus, applying the erase voltage removes most, if not all, charge stored on gate 18.

In contrast to conventional memory cells which have a floating gate with a work function of less than about 4.15 electron-volts, memory cell 10 offers superior Reliability, particularly resistance to the disturb effect. More specifically, the higher work function of floating gate 18 reduces the tunneling current that occurs in response to the erase voltage. The reduction stems not only from a greater barrier height (stemming from the greater work function) which the electrons must overcome to effect tunneling, but also from an increase in the tunneling distance. The reduction translates into a lower likelihood that inadvertent tunneling will occur - - - in other words, an effective resistance to the disturb effect.

In addition to the resistance to the disturb effect, the greater work function and consequent increase in barrier height and tunneling distance provide at least four other advantages. First, the greater work function increases the time-dependent dielectric breakdown (TDDB), that is, the life, of gate insulation layer 14. Second, the greater work function improves erase-cycle endurance, which means that the memory cell can endure many more erase cycles without degraded performance or failure. Third, the greater work function increases the barrier height and tunneling distance, not just for electrons, but also for holes (positive charges), thereby reducing hole injection, a contributant to undesirable variation in the threshold voltage of erased memory cells. Fourth, during write operations which require positive biasing of the control gate relative the drain region, the higher work function increases the kinetic energy of electrons arriving at the floating gate. Thus, for a given charge level, charging the higher-work-function floating gate requires a lower control gate voltage than gates with lesser work functions. Ultimately, this improves efficiency of the memory cell.

### Exemplary Disturb-resistant Memory Circuit

FIG. 2 shows an exemplary flash memory circuit system 40 that incorporates disturb-resistant memory cells of the present invention. Memory circuit 40, which operates according to well-known and understood principles, is generally coupled to a processor (not shown) to form a computer system. More particularly, circuit 40 includes a memory array 42 which comprises a number of memory cells 43, a column address decoder 44, and a row address decoder 45, bit lines 46, word lines 47, and voltage-sense-amplifier circuit 48 coupled in conventional fashion to bit lines 46. (For clarity, FIG. 2 omits many conventional elements of a memory circuit.)

In the exemplary embodiment, each of the memory cells is a disturb-resistant memory cell similar in form and function to memory cell 10 of FIG. 1. In addition, the exemplary memory array has a NOR array structure compatible with magnetic disk drives. Thus, each row of memory cells stores the equivalent of a typical magnetic disk sector, or 544 bytes (512 bytes of data plus 32 bytes of overhead.) Although the exemplary embodiment stores one data bit per memory cell, other embodiments store two or more bits per cell using a multi-bit storage technique.

### Conclusion

In furtherance of the art, the inventor has devised a disturb-resistant memory cell, which includes a floating gate having a work function greater than about 4.15 electron-volts, the work function of conventional polysilicon floating gates. Not only does the greater work function inhibit occurrence of the disturb effect and thereby safeguard data integrity, it also improves the reliability and efficiency of the memory cell, ultimately allowing fabrication of superior memory circuits and computer systems.

The embodiments described above are intended only to illustrate and teach one or more ways of practicing or implementing the present invention, not to restrict its breadth or scope. The actual scope of the invention, which embraces all ways of practicing or implementing the invention, is defined only by the following claims and their equivalents.

1. A nonvolatile memory cell comprising a floating gate having a work function greater than about 4.15 electron-volts.

2. The nonvolatile memory cell of claim 1, wherein the work function is approximately 4.3, 4.5, 4.55, 4.7, 4.9, 5.0, 5.1, 5.2, 5.6, or 6.0 electron-volts.

3. The nonvolatile memory cell of claim 1 wherein the floating gate comprises at least one of tungsten, nickel, copper, gold, silver, titanium silicide, titaniumnitride-tungsten alloy, platinum, iridium, and selenium.

4. The nonvolatile memory cell of claim 1, further comprising:
a semiconductive substrate containing a channel region; and
a first and second insulative layers located over the channel region, with the floating gate located between the first and second insulative layers.

5. The nonvolatile memory cell of claim 1, further comprising a control gate and a semiconductive substrate, each electrically isolated from the floating gate.

6. The nonvolatile memory cell of claim 1, further comprising a control gate which has a work function substantially different from that of the floating gate.

7. A nonvolatile memory cell comprising:
a semiconductive layer having a channel region;
a first and second insulative layers stacked over the channel region; and
a floating gate located between the first and second insulative layers and having a work function greater than 4.15 electron-volts.

8. The nonvolatile memory cell of claim 7, wherein the work function is approximately 4.3, 4.5, 4.55, 4.7, 4.9, 5.0, 5.1, 5.2, 5.6, or 6.0 electron-volts.

9. The nonvolatile memory cell of claim 7 wherein the floating gate comprises at least one of tungsten, nickel, copper, gold, silver, titanium silicide, titaniumnitride-tungsten alloy, platinum, iridium, and selenium.

10. The nonvolatile memory cell of claim 7, further comprising a control gate located on the second insulative layer and electrically isolated from the floating gate.

11. The nonvolatile memory cell of claim 7, wherein the floating gate is located over the channel region.

12. A nonvolatile memory cell comprising:
a semiconductive layer having a drain, source, and channel regions, with the drain region having a different diffusion depth than the source region;
a first and second insulative layers stacked over the channel region, with the first insulative layer closer to the channel region than the second insulative layer;
a floating gate located between the first and second insulative layers over the channel region, and having a work function greater than 4.15 electron-volts; and
a control gate located on the second insulative layer over the floating gate.

13. The nonvolatile memory cell of claim 12, wherein the work function is approximately 4.3, 4.5, 4.55, 4.7, 4.9, 5.0, 5.1, 5.2, 5.6, or 6.0 electron-volts.

14. The nonvolatile memory cell of claim 12 wherein the floating gate comprises at least one of tungsten, nickel, copper, gold, silver, titanium silicide, titaniumnitride-tungsten alloy, platinum, iridium, and selenium.

15. A nonvolatile memory cell comprising:
a semiconductive layer having a channel region;
a first and second insulative layers stacked over the channel region; and
a floating gate located between the first and second insulative layers and comprising at least one of tungsten, nickel, copper, gold, silver, titanium silicide, titanium-nitride-tungsten alloy, platinum, iridium, and selenium.

16. A nonvolatile memory cell comprising a floating gate having a work function of approximately 4.3, 4.5, 4.55, 4.7, 4.9, 5.0, 5.1, 5.2, 5.6, or 6.0 electron-volts.

17. A non-volatile memory cell comprising means for resisting the disturb effect, the means including a floating gate having a work function substantially different from 4.15 electron-volts.

18. The non-volatile memory cell of claim 17 wherein the work function is greater than about 4.15 electron-volts.

19. The non-volatile memory cell of claim 17 wherein the work function is approximately 4.3, 4.5, 4.55, 4.7, 4.9, 5.0, 5.1, 5.2, 5.6, or 6.0 electron-volts.

20. The non-volatile memory cell of claim 17 wherein the floating gate comprises at least one of one of tungsten, nickel, copper, gold, silver, titanium silicide, titanium-nitride-tungsten alloy, platinum, iridium, and selenium.

21. A non-volatile memory cell comprising means for resisting the disturb effect, the means including a floating gate having a non-conventional work function.

22. The non-volatile memory cell of claim 21 wherein the non-conventional work function is a work function greater than about 4.15 electron-volts.

23. The non-volatile memory cell of claim 21 wherein the floating gate has a work function of approximately 4.3, 4.5, 4.55, 4.7, 4.9, 5.0, 5.1, 5.2, 5.6, or 6.0 electron-volts.

24. The non-volatile memory cell of claim 21 wherein the floating gate comprises at least one of tungsten, nickel, copper, gold, silver, titanium silicide, titanium-nitride-tungsten alloy, platinum, iridium, and selenium.

25. A non-volatile memory cell comprising means for resisting the disturb effect, the means consisting essentially of a floating gate having a non-conventional work function.

26. The non-volatile memory cell of claim 1:
wherein the non-conventional work function is a work function greater than about 4.15 electron-volts;
wherein the floating gate has a work function of approximately 4.3, 4.5, 4.55, 4.7, 4.9, 5.0, 5.1. 5.2, 5.6, or 6.0 electron-volts; or
wherein the floating gate comprises at least one of tungsten, nickel, copper, gold, silver, titanium silicide, and titanium-nitride-tungsten alloy.

27. A non-volatile memory cell comprising means for reducing the tunneling current that occurs in response to an erase voltage, the means comprising a floating gate having a work function greater than 4.15 electron-volts.

28. A non-volatile memory cell comprising means for improving time-dependent dielectric breakdown, the means comprising a floating gate having a work function appreciably greater than 4.15 electron-volts.

29. A non-volatile memory cell comprising means for improving erase-cycle endurance, the means comprising a floating gate having a work function greater than 4.15 electron-volts.

30. A non-volatile memory cell comprising means for reducing hole injection, the means comprising a floating gate having a work function greater than 4.15 electron-volts.

31. A non-volatile memory cell comprising means for reducing undesirable variation in its threshold voltage after erasure, the means comprising a floating gate having a work function greater than 4.15 electron volts.

32. A non-volatile memory cell comprising means for reducing the write differential voltage required to charge its floating gate to a given charge level, the means comprising a floating gate having a work function greater than 4.15 electron volts.

33. A nonvolatile memory cell comprising a transistor with two gate members having substantially different work functions.

34. A non-volatile memory cell comprising a control gate and a floating gate which have substantially different work functions.

35. The non-volatile memory cell of claim 1 wherein the control gate has a work function of about 4.15 electron volts and the floating gate has a work function greater than that of the control gate.

36. A floating-gate transistor, comprising:
a first gate insulation layer;
a first gate on the gate insulation layer;
a second gate insulation layer;
a second gate on the second gate insulation layer, the second gate having a work function different from that of the first gate.

37. A floating-gate transistor comprising a floating gate having a work function greater than about 4.15 electron-volts.

38. The floating-gate transistor of claim 37, wherein the work function is approximately 4.3, 4.5, 4.55, 4.7, 4.9, 5.0, 5.1, 5.2, 5.6, or 6.0 electron-volts.

39. The floating-gate transistor of claim 37, wherein the floating gate comprises at least one of tungsten, nickel, copper, gold, silver, titanium silicide, titaniumnitride-tungsten alloy, platinum, iridium, and selenium.

40. A floating-gate transistor comprising means for resisting the disturb effect, the means comprising a floating gate having a work function substantially different from 4.15 electron-volts.

41. The floating-gate transistor of claim 40:
wherein the work function is greater than about 4.15 electron-volts;
wherein the floating gate has a work function of approximately 4.3, 4.5, 4.55, 4.7, 4.9, 5.0, 5.1, 5.2, 5.6, or 6.0 electron-volts; or
wherein the floating gate comprises at least one of tungsten, nickel, copper, gold, silver, titanium silicide, titanium-nitride-tungsten alloy, platinum, iridium, and selenium.

42. An integrated memory circuit comprising one or more floating-gate transistors, each of which comprises a floating gate having a work function greater than about 4.15 electron-volts.

43. The integrated memory circuit of claim 42, wherein the work function is approximately 4.3, 4.5, 4.55, 4.7, 4.9, 5.0, 5.1, 5.2, 5.6, or 6.0 electron-volts.

44. The integrated memory circuit of claim 42, wherein the floating gate comprises at least one of tungsten, nickel, copper, gold, silver, titanium silicide, titanium-nitride-tungsten alloy, platinum, iridium, and selenium.

45. An integrated memory circuit comprising:
one or more floating-gate transistors, each of which comprises a floating gate having a work function greater than about 4.15 electron-volts;
one or more address decoders coupled to the floating-gate transistors; and
one or more sense amplifiers coupled to the floating-gate transistors.

46. The integrated memory circuit of claim 45:
wherein the floating gate has a work function of approximately 4.3, 4.5, 4.55, 4.7, 4.9, 5.0, 5.1, 5.2, 5.6, or 6.0 electron-volts; or
wherein the floating gate comprises at least one of tungsten, nickel, copper, gold, silver, titanium silicide, titanium-nitride-tungsten alloy, platinum, iridium, and selenium.

47. A non-volatile integrated memory circuit comprising one or more floating-gate transistors, each of which comprises a floating gate having a work function greater than about 4.15 electron-volts.

48. The nonvolatile integrated memory circuit of claim 47, wherein the work function is approximately 4.3, 4.5, 4.55, 4.7, 4.9, 5.0, 5.1, 5.2, 5.6, or 6.0 electron-volts.

49. The nonvolatile memory cell of claim 48, wherein the floating gate comprises at least one of tungsten, nickel, copper, gold, silver, titanium silicide, titanium-nitride-tungsten alloy, platinum, iridium, and selenium.

50. A system comprising a processor and a memory circuit, wherein the memory circuit comprises one or more memory cells, each of which comprises a floating gate having a work function greater than about 4.15 electron-volts.

51. The system of claim 50:
wherein the floating gate has a work function of approximately 4.3, 4.5, 4.55, 4.7, 4.9, 5.0, 5.1, 5.2, 5.6, or 6.0 electron-volts; or
wherein the floating gate comprises at least one of tungsten, nickel, copper, gold, silver, titanium silicide, titanium-nitride-tungsten alloy, platinum, iridium, and selenium.

52. A computer system comprising a processor and a memory circuit, wherein the memory circuit comprises one or more memory cells, each of which comprises a floating gate having a work function greater than about 4.15 electron-volts.

53. The computer system of claim 52:
wherein the floating gate has a work function of approximately 4.3, 4.5, 4.55, 4.7, 4.9, 5.0, 5.1, 5.2, 5.6, or 6.0 electron-volts; or
wherein the floating gate comprises at least one of tungsten, nickel, copper, gold, silver, titanium silicide, titanium-nitride-tungsten alloy, platinum, iridium, and selenium.

54. A method of making a nonvolatile memory cell having disturb-resistance, the method comprising:
forming an insulative layer on a semiconductive layer;
forming a gate having a work function greater than about 4.15 electron-volts on the insulative layer;
forming an insulative layer over the gate; and
forming another gate on the insulative layer over the gate.

55. The method of claim 54, wherein forming the gate having a work function greater than about 4.15 electron-volts comprises:
depositing a material having a work function in the range of 4.2 to 6.0 electron-volts on the insulative layer; or
depositing at least one of tungsten, nickel, copper, gold, silver, titanium silicide, titanium-nitride-tungsten alloy, platinum, iridium, and selenium on the insulative layer.
